(19) United States
(12) Patent Application Publication
(10) Pub. No.: US 2013/0155611 A1
(43) Pub. Date: Jun. 20, 2013

(54) ELECTRONIC DEVICE HAVING DUST CLEANING APPARATUS

(71) Applicants: CHIH-HAO YANG, Tu-Cheng (TW); XIANG-KUN ZENG, Shenzhen City (CN); JING-JUN NI, Shenzhen City (CN)

(72) Inventors: CHIH-HAO YANG, Tu-Cheng (TW); XIANG-KUN ZENG, Shenzhen City (CN); JING-JUN NI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/571,452

(22) Filed: Aug. 10, 2012

(30) Foreign Application Priority Data
Dec. 20, 2011 (CN) 201110429305.0

(51) Int. Cl. H05K 7/20; H05K 7/00

(52) U.S. Cl. 361/692; 361/709; 361/697; 361/679.01; 361/700

(57) ABSTRACT

An electronic device includes a bottom plate, a cover plate, a dust collection box, and a dust cleaning apparatus. A heat sink is mounted in the bottom plate. The cover plate covers on the bottom plate. The cover plate defines a cutout. The dust collection box is placed on the bottom plate via the cutout. The dust cleaning apparatus is slidably mounted on the bottom plate. The dust cleaning apparatus moves relative to the heat sink to sweep dust of the heat sink into the dust collection box.

### BACKGROUND

1. Technical Field

The present disclosure relates to electronic devices, and more particularly to an electronic device having a dust cleaning apparatus.

2. Description of Related Art

Electronic devices, such as notebook computers, are usually equipped with fans and heat sinks to dissipate heat from the electronic devices. However, after the electronic devices are used for a long time, dust may accumulate on the heat sinks. The dust lowers efficiency of the heat sinks dissipating heat. It often needs to detach the electronic device to clean the dust, which may damage the electronic device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of one embodiment of an electronic device.

FIG. 2 is a partially assembled view of the electronic device of FIG. 1.

FIG. 3 is partially assembled view of the electronic device of FIG. 1.

FIG. 4 is an assembled view of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

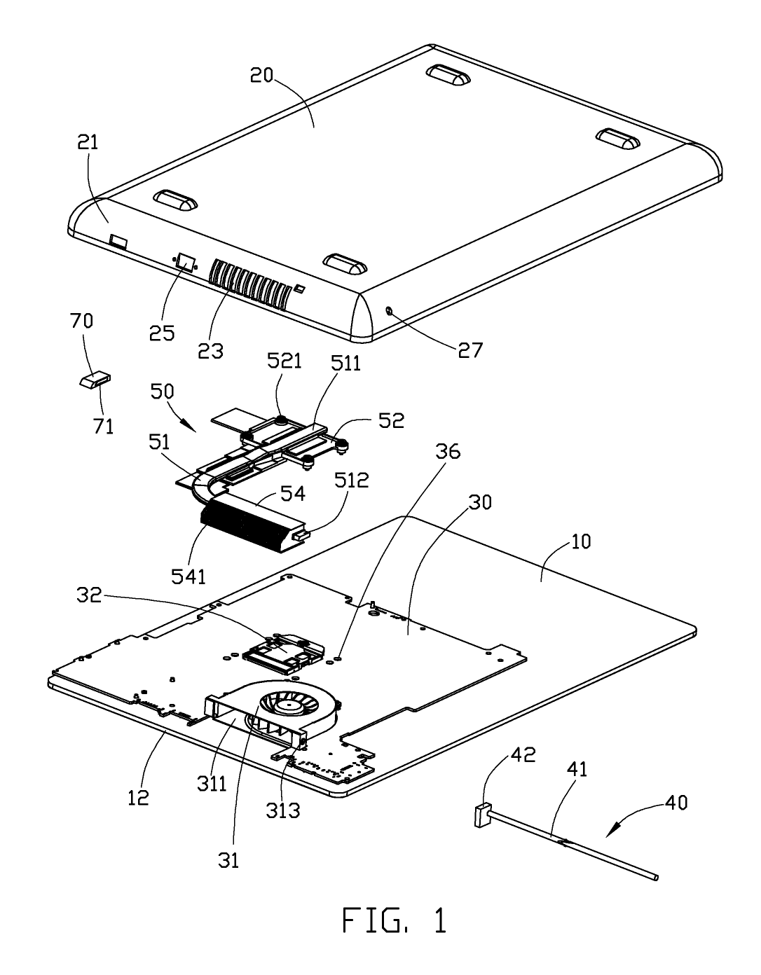

Referring to FIG. 1, an embodiment of an electronic device is shown. The electronic device includes an enclosure. The enclosure includes a bottom plate 10 and a cover plate 20. A dust cleaning apparatus 40 and a dust collection box 70 are mounted in the enclosure.

The bottom plate 10 includes a side edge 12. A printed circuit board 30 is mounted on the bottom plate 10 and located adjacent to the side edge 12. A heat generation apparatus 32 and a fan 31 are mounted on the printed circuit board 30. The printed circuit board 30 defines a plurality of securing holes 36 around the heat generation apparatus 32. The fan 31 defines an air outlet 311, which is adjacent to the side edge 12. The fan 31 further defines a first ducting hole 313. In one embodiment, the fan 31 is a turbine fan.

A heat dissipation apparatus 50 can be mounted on the printed circuit board 30. The heat dissipation apparatus 50 includes a heat pipe 51. The heat pipe 51 is bent to be formed in an “L” shape. The heat pipe 51 includes a first end 511 and a second end 512. The first end 511 is secured to a top surface of a heat conduction piece 52. The heat conduction piece 52 includes a plurality of securing posts 521 corresponding to the plurality of securing holes 36 of the printed circuit board 30. The second end 512 is secured to a heat sink 54. The heat sink 54 includes a plurality of parallel fins 541. Two adjacent fins of the plurality of parallel fins 541 define an air passage.

The dust cleaning apparatus 40 includes a rod 41 and a dust sweeping piece 42. The dust sweeping piece 42 is secured to one end of the rod 41.

The cover plate 20 can be mounted on the bottom plate 10. A flange 21 is formed on sides of the cover plate 20. The flange 21 defines a plurality of air vents 23 corresponding to the air outlet 311 of the fan 31. A cutout 25 is defined in the flange 21. The flange 21 further defines a second guiding hole 27 corresponding to the first guiding hole 313 of the fan 31.

The dust collection box 70 can be placed in the electronic device via the cutout 25. The dust collection box 70 defines an opening 71.

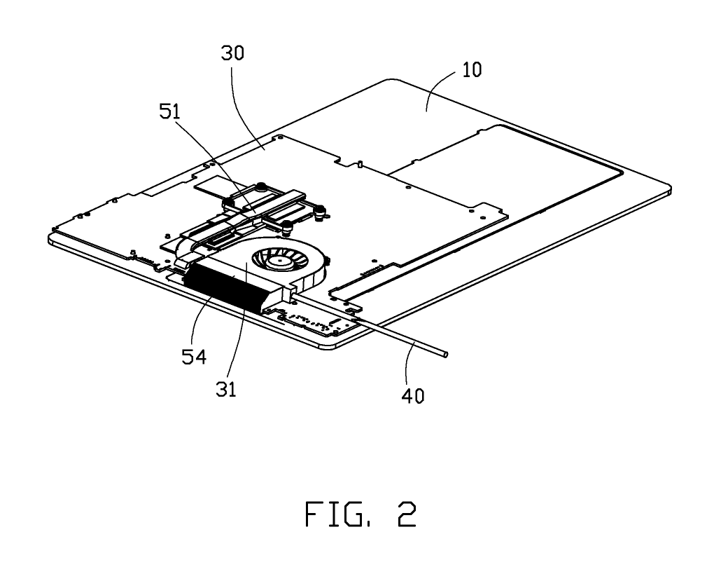

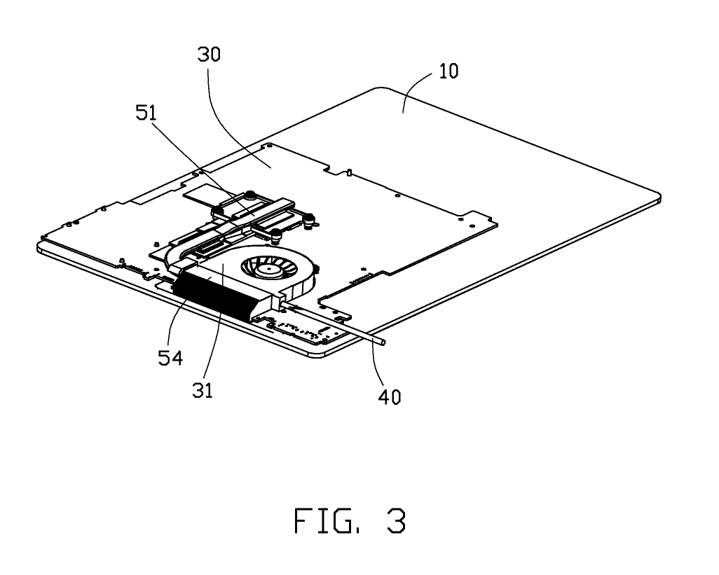

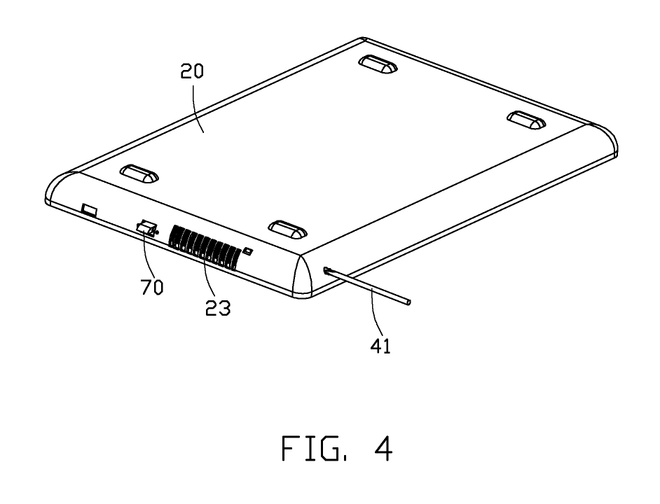

Referring to FIGS. 1 to 4, in assembly, the rod 41 of the dust cleaning apparatus 40 is inserted in the first guiding hole 313 of the fan. The rod 41 slides in the first guiding hole 313 to move the dust sweeping piece 42 in the air outlet 311. The heat conduction piece 52 is located on the heat generation apparatus 32 and thermally contacts the heat generation apparatus 32. The plurality of securing posts 521 is secured in the plurality of securing holes 36 to secure the heat dissipation apparatus 50 on the printed circuit board 30. At this position, the heat sink 54 is located in alignment with the air outlet 311 of the fan 31. The dust sweeping piece 42 abuts edges of the plurality of fins 541 of the heat sink 54. Then, the cover plate 20 is mounted on the bottom plate, and the rod 41 is inserted in the second guiding hole 27 of the cover plate 20 to be located out of the electronic device. The dust collection box 70 is placed in the electronic device via the cutout 25 of the cover plate 20. The opening 71 of the dust collection box 70 faces to the dust sweeping piece 42.

When it needs to clean dust which is accumulated on the plurality of fins 541 of the heat sink 54, the rod 41 is drawn to move the dust sweeping piece 42 in the electronic device. The dust sweeping 42 sweeps dust from the plurality of fins 541 of the heat sink 54 into the dust collection box 70 via opening 71. The dust collection box 70 is then taken out of the electronic device via the cutout 25. Dust in the dust collection box 70 is then easily cleaned.

In the electronic device, the dust cleaning apparatus 40 and the dust collection box 70 clean dust in the electronic device without opening the cover of the electronic device.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device, comprising:
a bottom plate with a heat sink mounted thereon;
a cover plate covered on the bottom plate, the cover plate defining a cutout;
a dust collection box configured to be placed on the bottom plate via the cutout; and
a dust cleaning apparatus slidably mounted on the bottom plate, the dust cleaning apparatus configured to move relative to the heat sink to sweep dust on the heat sink into the dust collection box.

2. The electronic device of claim 1, wherein a fan is located adjacent to the heat sink, the fan defines an air outlet which faces to the heat sink.

3. The electronic device of claim 2, wherein the fan defines a first guiding hole, the dust cleaning apparatus comprises a rod and a dust sweeping piece connected to a first end of the rod, a second end of the rod is inserted through the first guiding hole, and the dust sweeping piece abuts the heat sink and is movably in the air outlet.

4. The electronic device of claim 3, wherein the cover plate defines a second guiding hole in alignment with the first guiding hole, and the second end of the rod is inserted through the second guiding hole to be located out of the cover plate.

5. The electronic device of claim 3, wherein the dust collection box defines a cutout which faces to the dust sweeping piece.

6. The electronic device of claim 1, wherein a printed circuit board is mounted on the bottom plate, a heat generation apparatus comprising a heat pipe is located on the printed circuit board, and the heat pipe thermally contacts the heat generation apparatus and the heat sink.

7. The electronic device of claim 6, wherein the heat sink comprises a plurality of parallel fins which abuts the dust sweeping piece, and two adjacent fins of the plurality of parallel fins define an air passage therebetween.

8. The electronic device of claim 1, wherein the cover defines a plurality of air vents in alignment with the heat sink.

9. An electronic device, comprising:
an enclosure with a component mounted therein, the enclosure defining a cutout and a guiding hole;
a dust collection box configured to be placed on the bottom plate via the cutout; and
a dust cleaning apparatus comprising a rod and a dust sweeping piece connected to a first end of the rod, a second end of the rod inserted through the guiding hole to be located out of the enclosure, the dust sweeping piece located in the enclosure and abutting the component; wherein the second end of the rod is configured to be drawn to move the dust sweeping piece in the enclosure to sweep the dust of the component into the dust collection box.

10. The electronic device of claim 9, wherein a fan is located adjacent to the component, the fan defines an air outlet which faces to the component.

11. The electronic device of claim 10, wherein the fan defines a first guiding hole, the second end of the rod is inserted through the first guiding hole, and the dust sweeping piece is movably in the air outlet.

12. The electronic device of claim 9, wherein the dust collection box defines a cutout which faces to the dust sweeping pieces.

13. The electronic device of claim 9, wherein the enclosure comprises a bottom plate, the component is a heat sink, a printed circuit board is mounted on the bottom plate, a heat generation apparatus with a heat pipe is mounted on the printed circuit board, the heat pipe is in contact with the heat generation apparatus and the heat sink.

14. The electronic device of claim 13, wherein the heat sink comprises a plurality of parallel fins which abuts the dust sweeping piece, and two adjacent fins of the plurality of parallel fins define an air passage therebetween.

15. The electronic device of claim 13, wherein the enclosure defines a plurality of air vents which is in alignment with the heat sink.
